(19) United States
(12) Patent Application Publication
(10) Pub. No.: US 2010/0330756 A1
(43) Pub. Date: Dec. 30, 2010

(54) INTEGRATED CIRCUIT STRUCTURE MANUFACTURING METHODS USING HARD MASK AND PHOTORESIST COMBINATION

(75) Inventors: Veeraraghavan S. Basker, Albany, NY (US); Toshiharu Furukawa, Essex Junction, VT (US); Steven J. Holmes, Hopewell Junction, NY (US)

Correspondence Address: FREDERICK W. GIBB, III;Gibb Intellectual Property Law Firm, LLC, 844 West Street, SUITE 100, ANNAPOLIS, MD, 21401, US

(73) Assignee: INTERNATIONAL BUSINESS MACHINES CORPORATION, ARMONK, NY (US)

(21) Appl. No.: 12/491,270

(22) Filed: Jun. 25, 2009

(51) Int. Cl. H01L 21/8238

(52) U.S. Cl. 438/229; 257/E21.632

(57) ABSTRACT

A method of manufacturing an integrated circuit structure implants a first-type of channel implant in a first area of a substrate and implants a second-type of channel implant in a second area of the substrate. The method forms at least one first gate conductor above the first area of the substrate and forms at least one second gate conductor above the second area of the substrate. The method forms a hard mask over the first gate conductor, the second gate conductor, and the substrate. The hard mask comprises an oxide or a nitride and patterns an organic photoresist over the hard mask, to leave the organic photoresist on areas of the hard mask that are above the first area of the substrate. The method removes portions of the hard mask not protected by the organic photoresist to leave the hard mask on the first area of the substrate and not on the second area of the substrate. The method then removes the organic photoresist, implants impurities in the second area of the substrate to form source and drain regions adjacent the second gate conductor; and removes the hard mask using a wet etching process.

### BACKGROUND

1. Field of the Invention

The embodiments of the invention generally relate to semiconductor transistors and more particularly relate to a method that utilizes a hard mask in combination with a photoresist mask during the source/drain impurity implantation processing to eliminate undesirable damage to the source/drain regions when the hard mask is removed.

2. Description of the Related Art

Complimentary metal oxide semiconductor (CMOS) transistors utilize transistors that have opposite types of characteristics depending upon the dopants used. These opposite type transistors are commonly referred to as positive-type (P-type) and negative-type (N-type) transistors.

When implanting impurities for the source/drain regions, an organic photoresist can be patterned to provide an implant block mask that protects one type of transistor while the impurities are implanted into the opposite type transistor. However, the process of removing this photoresist may damage the source/drain regions. More specifically, dopant loss during stripping of the implant block mask resist is a problem, especially as scaled devices require shallower and highly doped junction formation. The problem is most serious for the S/D (source and drain) extension implantation. The loss of the dopant from the extension implanted area under the spacer causes a severe degradation in series resistance of the field effect transistor (FET) device because there is no silicide formed under the spacer.

When an organic photoresist is used as the implant block mask, a “crust” layer is formed by heavy ion bombardment during the ion implantation. The crust layer is a highly polymerized carbon rich compound which is not easily etched without a strong oxidizing etch such as O₂RIE or high temperature wet S/P (sulfuric acid and hydrogen peroxide). However, these strong oxidizing etches oxidize the exposed implanted silicon substrate and, as a result, a significant amount of the dopant can be lost.

### SUMMARY

In view of these issues, disclosed herein is a method of manufacturing an integrated circuit structure that uses a combination of a hard mask and a photoresist in order to reduce damage to implanted impurities. The method implants a first-type of channel implant in a first area of a substrate and implants a second-type of channel implant in a second area of the substrate to form the well regions of different transistors. A shallow trench isolation region is formed in the substrate between the first-type of channel implant and the second-type of channel implant. The method also forms gates above the well regions by forming at least one first gate conductor above the first area of the substrate and at least one second gate conductor above the second area of the substrate. The gate formation process includes any necessary gate oxides, gate caps, etc.

Rather than forming conventional organic photoresists to accomplish source and drain doping, the present embodiments form a first hard mask over the first gate conductor(s), the second gate conductor(s), and the substrate. The first hard mask comprises an oxide, a nitride, etc. Then, a first organic photoresist is patterned over the first hard mask so as to leave the first organic photoresist on areas of the first hard mask that are above the first area of the substrate. The method then removes the portions of the first hard mask that are not protected by the first organic photoresist to leave the first hard mask on the first area of the substrate and not on the second area of the substrate.

Once the first organic photoresist has been used to pattern the first hard mask, the method removes the first organic photoresist and implants second-type impurities in the second area of the substrate to form second source and drain regions (e.g., source drain extensions) adjacent the second gate conductor. The method then grows second spacers on the second gate conductor and implants additional second-type impurities in the second area of the substrate to form additional second source and drain regions adjacent the second source and drain extensions.

The first hard mask is then removed using a wet etching process. Then, the method forms a second hard mask over the first gate conductor(s), the second gate conductor(s), and the substrate. As with the first hard mask, the second hard mask comprises an oxide, a nitride, etc. For example, the first hard mask and the second hard mask can comprise silicon nitride (Si₃N₄), compositions of SiGeOx such that Ge more than 60% (but less than 100%) relative to Si, etc. The method also patterns a second organic photoresist over the second hard mask, to leave the organic photoresist on areas of the second hard mask that are above the second area of the substrate. The method similarly removes portions of the second hard mask not protected by the organic photoresist to leave the second hard mask on the second area of the substrate and not on the first area of the substrate.

As with the first doping process, the method then removes the second organic photoresist and implants first-type impurities in the first area of the substrate to form first source and drain regions (e.g., source and drain extensions) adjacent the first gate conductor. First spacers are then grown on the first gate conductor and additional first-type impurities are implanted in the first area of the substrate to form additional first source and drain regions adjacent the first source and drain extensions.

After performing such a doping process, the method removes the second hard mask using a wet etching process and then silicides the first gate conductor, the first source and drain regions, the first source and drain extensions, the second gate conductor, the second source and drain regions, and the second source and drain extensions.

The first-type of channel implant, the first gate conductor, the first source and drain extensions, and the first source and drain regions combine to form a first-type transistor. The second-type of channel implant, the second gate conductor, the second source and drain extensions, and the second source and drain regions combine to form a second-type transistor.

The wet etching process used to remove the first and second hard masks is selective to the substrate, the first-type impurities, and the second-type impurities. Therefore, the wet etching process does not damage the substrate, the first source and drain extensions, the second source and drain extensions, the first source and drain regions, or the second source and drain regions.

As mentioned above, the first and second hard mask can comprise silicon nitride (Si₃N₄), SiGeOx with Ge at least 60% relative to Si) etc.; however, the first hard mask and the second hard mask can be formed by growing a silicon oxide (SiO₂) liner on the first gate conductor, the second gate conductor, and the substrate; and depositing a germanium (Ge) layer on the silicon oxide liner. Alternatively, the first hard mask and second hard mask can be formed by depositing a silicon nitride (Si₃N₄) liner on the first gate conductor, the second gate conductor, and the substrate followed by growing a silicon dioxide (SiO₂) layer on the silicon nitride liner.

Therefore, as shown above, instead of using an organic photoresist as an implant blocking mask, an inorganic hard mask material is used as the blocking mask. The hard mask material is chosen so that, after the implantation, the material can be easily removed selectively to the implanted silicon substrate without causing any damage to the implanted source/drain regions or their extensions.

### BRIEF DESCRIPTION OF THE DRAWINGS

The embodiments of the invention will be better understood from the following detailed description with reference to the drawings, which are not necessarily drawing to scale and in which

FIG. 1 is a flowchart illustrating method embodiments herein;

FIG. 2 is a schematic cross-sectional drawing of an integrated circuit structure according to embodiments herein;

FIG. 3 is a schematic cross-sectional drawing of an integrated circuit structure according to embodiments herein;

FIG. 4 is a schematic cross-sectional drawing of an integrated circuit structure according to embodiments herein;

FIG. 5 is a schematic cross-sectional drawing of an integrated circuit structure according to embodiments herein;

FIG. 6 is a schematic cross-sectional drawing of an integrated circuit structure according to embodiments herein.

FIG. 7 is a schematic cross-sectional drawing of an integrated circuit structure according to embodiments herein;

FIG. 8 is a schematic cross-sectional drawing of an integrated circuit structure according to embodiments herein;

FIG. 9 is a schematic cross-sectional drawing of an integrated circuit structure according to embodiments herein; and

FIG. 10 is a schematic cross-sectional drawing of an integrated circuit structure according to embodiments herein.

### DETAILED DESCRIPTION

The embodiments of the invention and the various features and advantageous details thereof are explained more fully with reference to the non-limiting embodiments that are illustrated in the accompanying drawings and detailed in the following description.

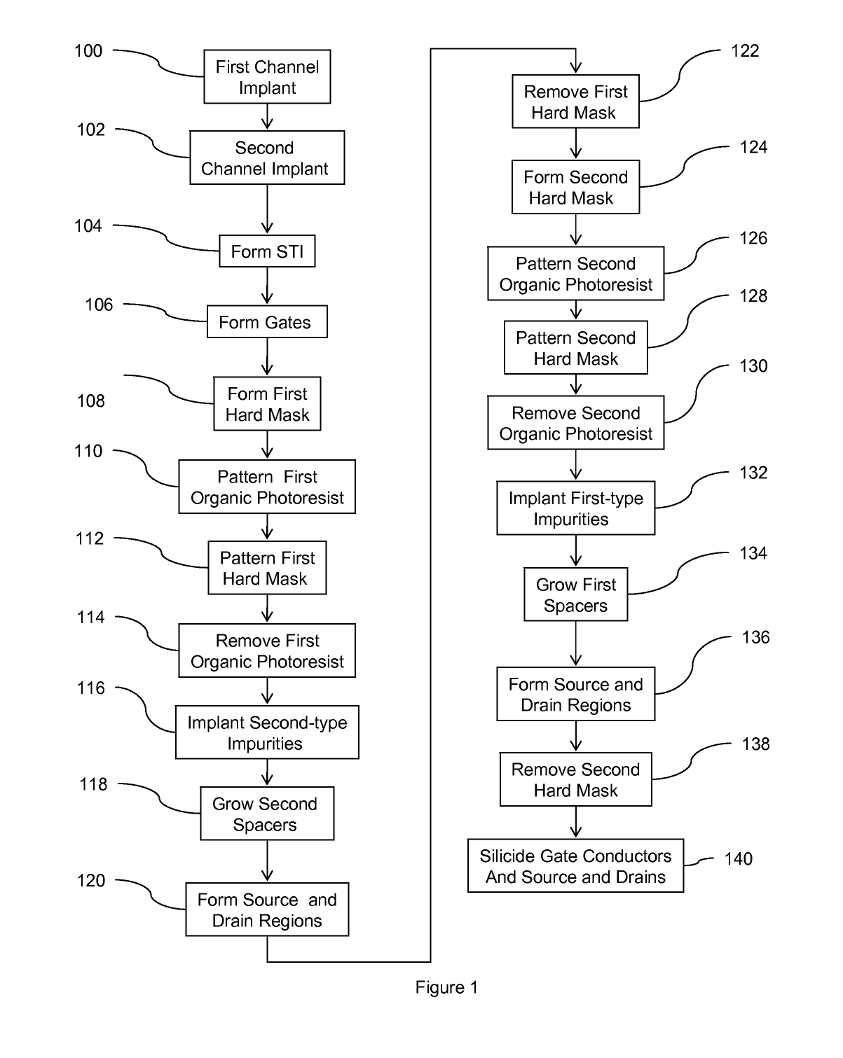

Disclosed herein is a method of manufacturing an integrated circuit structure that uses a combination of a hard mask and a photoresist in order to reduce damage to implanted impurities. As shown in flowchart form in FIG. 1, the method implants a first-type of channel implant (100) in a first area of a substrate and implants a second-type of channel implant (102) in a second area of the substrate to form the well regions of different transistors. A shallow trench isolation (STI) region is formed in the substrate between the first-type of channel implant and the second-type of channel implant in item 104.

The method also forms gates above the well regions by forming at least one first gate conductor above the first area of the substrate and at least one second gate conductor above the second area of the substrate in item 106. The gate formation process includes any necessary gate oxides, gate caps, etc.

Rather than forming conventional organic photoresists to accomplish source and drain doping, the present embodiments form a first hard mask over the first gate conductor(s), the second gate conductor(s), and the substrate in item 108. The first hard mask comprises an oxide, a nitride, etc. Then, a first organic photoresist is patterned over the first hard mask (110) so as to leave the first organic photoresist on areas of the first hard mask that are above the first area of the substrate. The method then removes the portions of the first hard mask that are not protected by the first organic photoresist (112) to leave the first hard mask on the first area of the substrate and not on the second area of the substrate.

Once the first organic photoresist has been used to pattern the first hard mask, the method removes the first organic photoresist (114) and implants second-type impurities in the second area of the substrate (116) to form second source and drain regions (e.g., source drain extensions) adjacent the second gate conductor. The method then grows second spacers on the second gate conductor (118) and implants additional second-type impurities in the second area of the substrate (120) to form additional second source and drain regions adjacent the second source and drain extensions.

The first hard mask is then removed using a wet etching process in item 122. Then, the method forms a second hard mask over the first gate conductor(s), the second gate conductor(s), and the substrate in item 124. As with the first hard mask, the second hard mask comprises an oxide, a nitride, etc. For example, the first hard mask and the second hard mask can comprise silicon nitride (Si₃N₄), SiGeOx with Ge at least 60% relative to Si) etc.

The method also patterns a second organic photoresist over the second hard mask in item 126, to leave the organic photoresist on areas of the second hard mask that are above the second area of the substrate. The method similarly removes portions of the second hard mask not protected by the organic photoresist (128) to leave the second hard mask on the second area of the substrate and not on the first area of the substrate.

As with the first doping process, the method then removes the second organic photoresist (130) and implants first-type impurities in the first area of the substrate (132) to form first source and drain regions (e.g., source and drain extensions) adjacent the first gate conductor. First spacers are then grown on the first gate conductor (134) and additional first-type impurities are implanted in the first area of the substrate (136) to form additional first source and drain regions adjacent the first source and drain extensions.

After performing such a doping process, the method removes the second hard mask using a wet etching process (138) and then silicides the first gate conductor, the first source and drain regions, the first source and drain extensions, the second gate conductor, the second source and drain regions, and the second source and drain extensions in item 140.

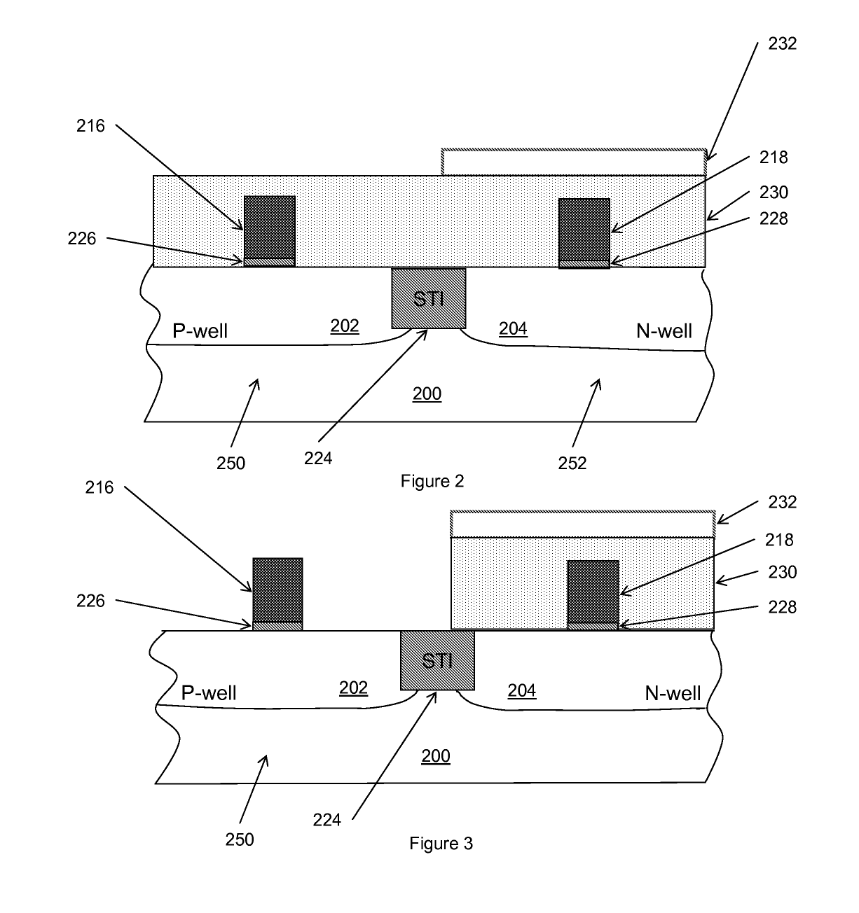

FIGS. 2-10 illustrate this process and the resulting structure using cross-sectional schematic diagrams. Referring now to FIG. 2, the method implants a first-type of channel implant 202 in a first area 252 of a substrate 200 and implants a second-type of channel implant 204 in a second area 250 of the substrate 200 to form the well regions of different transistors. The substrate can comprise any material appropriate for the given purpose (whether now known or developed in the future) and can comprise, for example, Si, SiC, SiGe, SiGeC, Ge alloys, GaAs, InAs, TnP, other III-V or II-VI compound semiconductors, or organic semiconductor structures etc. The implantation processes mentioned herein can take any appropriate form (whether now known or developed in the future) and can comprise, for example, ion implantation, etc. Also see U.S. Pat. No. 6,815,317 (incorporated herein by reference) for a full discussion of implantation techniques.

A shallow trench isolation region 224 is formed in the substrate 200 between the first-type of channel implant 202 and the second-type of channel implant 204. The method also forms gates above the well regions by forming at least one first gate conductor 218 above the first area 252 of the substrate 200 and at least one second gate conductor 216 above the second area 250 of the substrate 200. The gate conductors mentioned herein can comprise polysilicon, metals, metal alloys, or any other conductor. The gate formation process includes any necessary gate oxides 226, 228, gate caps, etc.

Rather than forming conventional organic photoresists to accomplish source and drain doping, the present embodiments form a first hard mask 230 over the first gate conductor 218(s), the second gate conductor 216(s), and the substrate 200. The hard masks mentioned herein comprise an oxide, a nitride, etc., and can be applied using any suitable process such as spin-on processing, etc. For example, the hard masks mentioned herein can comprise a material such as SixGeI-xO₂, (where x from 1 to 0) which can be removed by a diluted HF or COR; or can comprise SixGeI-x (where x from 0 to 0.6) which can be removed by a diluted H₂O₂/HF mixture after the ion implantation.

Then, a first organic photoresist 232 is patterned over the first hard mask 230 so as to leave the first organic photoresist 232 on areas of the first hard mask 230 that are above the first area 252 of the substrate 200. The photoresist masks mentioned herein can comprise any commonly known photoresist masks, such as organic photoresists that are exposed to a pattern of light and developed to allow openings to form in the mask.

Referring now to FIG. 3, the method then removes the portions of the first hard mask 230 that are not protected by the first organic photoresist 232 to leave the first hard mask 230 on the first area 252 of the substrate 200 and not on the second area 250 of the substrate 200.

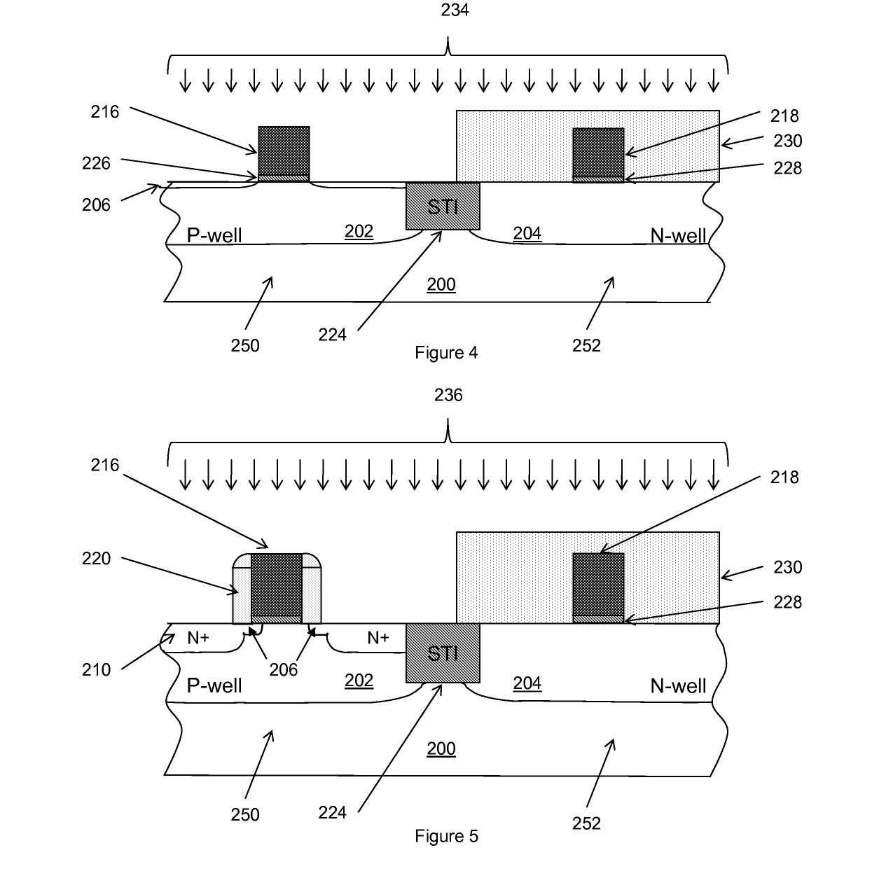

As shown in FIG. 4, once the first organic photoresist 232 has been used to patterned the first hard mask 230, the method removes the first organic photoresist 232 and implants second-type impurities 234 in the second area 250 of the substrate 200 to form second source and drain regions (e.g., source drain extensions 206) adjacent the second gate conductor 216.

As shown in FIG. 5, the method then grows second spacers 220 (e.g., nitrides, oxides, etc.) on the second gate conductor 216 and implants additional second-type impurities 236 in the second area 250 of the substrate 200 to form second source and drain regions 210 adjacent the second source and drain extensions.

The first hard mask 230 is then removed using a wet etching process. As mentioned above, the hard masks utilized herein can be removed by using diluted HF, COR, H₂O₂/HF, etc., mixtures after the ion implantation. Such wet etching process aggressively attacks the hard mask material, but has almost no affect on the silicon substrate. Therefore, such wet etching processes are considered to be highly selective to the hard mask material. Because of the high selectivity of the wet etch of the hard mask to the implanted substrate 200, the dopant and the silicon substrate loss are minimized. In other words, because the embodiments herein remove the organic material of the photoresist 232 before the ion implantation process is performed, no hard crust material is formed (as mentioned above, a crust may occur if the organic photoresists 232 were left in place). Since no hard crust layer is formed, aggressive material removal processing is not necessary with the embodiments herein, which allows the source/drain implantations and their extensions to remain relatively unaffected within the substrate.

As shown in FIG. 6, the method forms a second hard mask 240 over the first gate conductors 218, the second gate conductors 216, and the substrate 200. As with the first hard mask 230, the second hard mask 240 comprises an oxide, a nitride, etc. For example, the first hard mask 230 and the second hard mask 240 can comprise silicon nitride (Si₃N₄), germanium oxide (GeO₂), etc. The method also patterns a second organic photoresist 238 over the second hard mask 240, to leave the second organic photoresist 238 on areas of the second hard mask 240 that are above the second area 250 of the substrate 200.

As mentioned above, the first and second hard mask 240 can comprise, for example, silicon nitride (Si₃N₄), SiGeOx with Ge at least 60% relative to Si) etc.; however, the first hard mask 230 and the second hard mask 240 can be formed by growing a silicon oxide (SiO2) liner on the first gate conductor 218, the second gate conductor 216, and the substrate 200; and depositing a germanium (Ge) layer on the silicon oxide liner. Alternatively, the first hard mask 230 and second hard mask 240 can be formed by depositing a silicon nitride (Si₃N₄) liner on the first gate conductor 218, the second gate conductor 216, and the substrate 200 followed by growing a silicon dioxide (SiO2) layer on the silicon nitride liner.

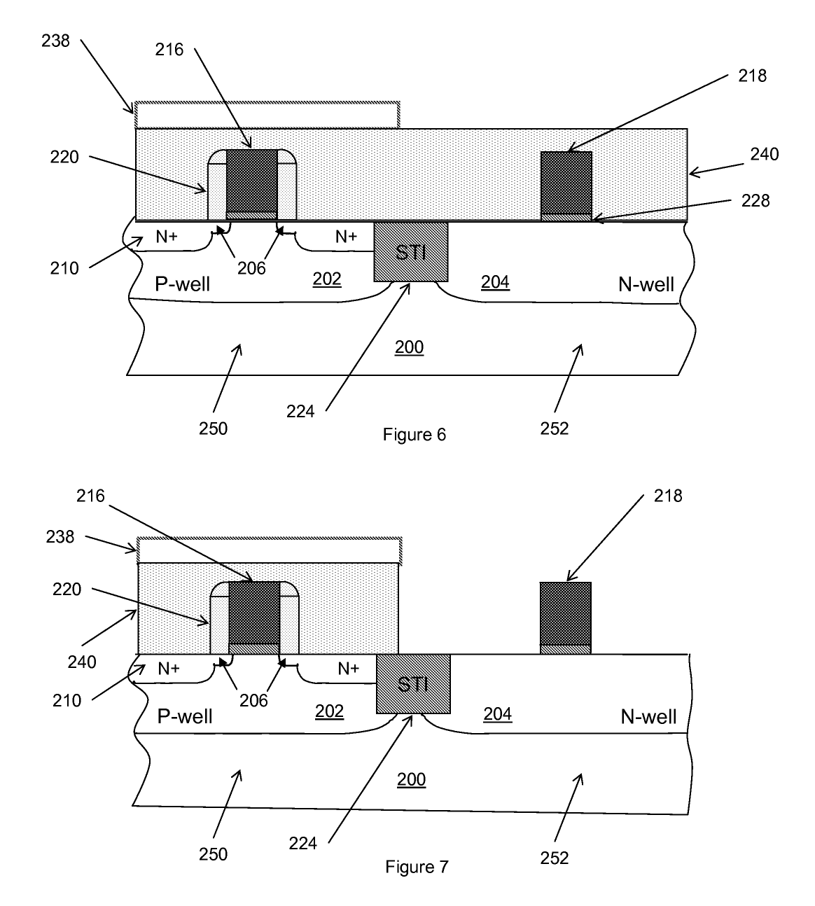

As shown in FIG. 7, the method similarly removes portions of the second hard mask 240 not protected by the organic photoresist to leave the second hard mask 240 on the second area 250 of the substrate 200 and not on the first area 252 of the substrate 200.

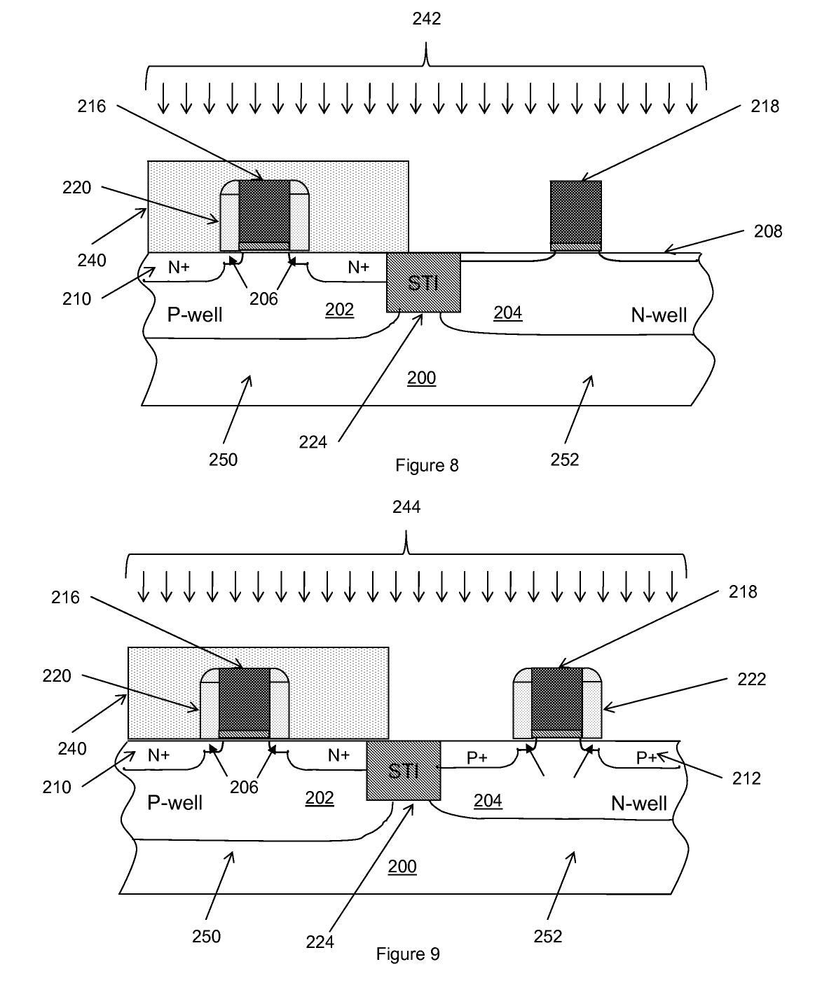

As with the first doping process, the method then removes the second organic photoresist 238 and implants first-type impurities 242 in the first area 252 of the substrate 200 to form first source and drain regions (e.g., source and drain extensions 208) adjacent the first gate conductor 218, as shown in FIG. 8. First spacers 222 are then grown on the first gate conductor 218 and additional first-type impurities 244 are implanted in the first area 252 of the substrate 200 to form additional first source and drain regions 212 adjacent the first source and drain extensions 208, as shown in FIG. 9.

Again, the wet etching process used to remove the first and second hard masks 230, 240 is selective to the substrate 200, the first-type impurities 242, 244, and the second-type impurities 234, 236. Therefore, the wet etching process does not damage the substrate 200, the first source and drain extensions 208, the second source and drain extensions 206, the first source and drain regions 212, or the second source and drain regions 210. Once again, since no hard crust layer is formed, aggressive material removal processing is not necessary with the embodiments herein, which allows the source/drain implantations and their extensions to remain relatively unaffected within the substrate.

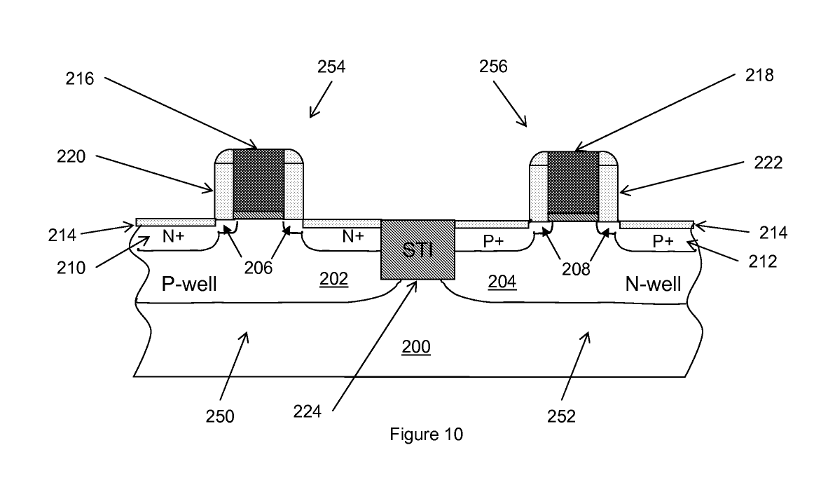

As shown in FIG. 10, after performing such a doping process, the method removes the second hard mask 240 using a wet etching process and then silicides 214 the first gate conductor 218, the first source and drain regions 212, the first source and drain extensions 208, the second gate conductor 216, the second source and drain regions 210, and the second source and drain extensions 206.

The first-type of channel implant 202, the first gate conductor 218, the first source and drain extensions 208, and the first source and drain regions 212 combine to form a first-type transistor 256. The second-type of channel implant 204, the second gate conductor 216, the second source and drain extensions 206, and the second source and drain regions 210 combine to form a second-type transistor 254 that is complementary to the first transistor 256. The second-type impurities comprises any positive-type impurity (P-type impurity, e.g., phosphorus (P), arsenic (As), antimony (Sb) etc.) and the first-type impurity comprises any negative-type impurity (N-type impurity, e.g., boron, indium, etc.). In addition to the methods discussed herein, and any other methodologies can be utilized to form the various transistors mentioned here, such as those discussed in U.S. Pat. No. 7,491,598 (incorporated herein by reference).

Therefore, as shown above, instead of using an organic photoresist as an implant blocking mask, an inorganic hard mask material is used as the blocking mask. The hard mask material is chosen so that, after the implantation, the material can be easily removed selectively to the implanted silicon substrate without causing any damage to the implanted source/drain regions or their extensions.

The resulting integrated circuit chip can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the corresponding structures, materials, acts, and equivalents of all means or step plus function elements in the claims below are intended to include any structure, material, or act for performing the function in combination with other claimed elements as specifically claimed. Additionally, it should be understood that the above-description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated. Well-known components and processing techniques are omitted in the above-description so as to not unnecessarily obscure the embodiments of the invention.

Finally, it should also be understood that the terminology used in the above-description is for the purpose of describing particular embodiments only and is not intended to be limiting of the invention. For example, as used herein, the singular forms “a”, “an” and “the” are intended to include the plural forms as well, unless the context clearly indicates otherwise. Furthermore, as used herein, the terms “comprises”, “comprising,” and/or “incorporating” when used in this specification, specify the presence of stated features, integers, steps, operations, elements, and/or components, but do not preclude the presence or addition of one or more other features, integers, steps, operations, elements, components, and/or groups thereof.

What is claimed is:

1. A method of manufacturing an integrated circuit structure, said method comprising:
implanting a first-type of channel implant in a first area of a substrate;
implanting a second-type of channel implant in a second area of said substrate;
forming at least one first gate conductor above said first area of said substrate;
forming at least one second gate conductor above said second area of said substrate;
forming a hard mask over said first gate conductor, said second gate conductor, and said substrate, said hard mask comprising one of an oxide and a nitride;
patterning an organic photoresist over said hard mask, to leave said organic photoresist on areas of said hard mask that are above said first area of said substrate;
removing portions of said hard mask not protected by said organic photoresist to leave said hard mask on said first area of said substrate and not on said second area of said substrate;
removing said organic photoresist;
implanting impurities in said second area of said substrate to form source and drain regions adjacent said second gate conductor; and
removing said hard mask using a wet etching process,
said second-type of channel implant, said second gate conductor, and said source and drain regions comprising a transistor.

2. The method according to claim 1, said wet etching process being selective to said substrate and said impurities such that said wet etching process does not damage said substrate or said source and drain regions.

3. The method according to claim 1, said hard mask comprising one of silicon nitride (Si₃N₄), and germanium silicon oxide (GeSiOx) where Ge composition is at least 60% but less than 100%.

4. The method according to claim 1, said forming of said hard mask comprising:
growing a silicon oxide (SiO₂) liner on said first gate conductor, said second gate conductor, and said substrate; and
depositing a germanium (Ge) layer on said silicon oxide liner.

5. The method according to claim 1, said forming of said hard mask comprising:
depositing a silicon nitride (Si₃N₄) liner on said first gate conductor, said second gate conductor, and said substrate; and
growing a silicon dioxide (SiO₂) layer on said silicon nitride liner.

6. The method according to claim 1, further comprising forming a shallow trench isolation region in said substrate between said first-type of channel implant and said second-type of channel implant.

7. A method of manufacturing an integrated circuit structure, said method comprising:
implanting a first-type of channel implant in a first area of a substrate;
implanting a second-type of channel implant in a second area of said substrate;
forming at least one first gate conductor above said first area of said substrate;
forming at least one second gate conductor above said second area of said substrate;
forming a hard mask over said first gate conductor, said second gate conductor, and said substrate, said hard mask comprising one of an oxide and a nitride;
patterning an organic photoresist over said hard mask, to leave said organic photoresist on areas of said hard mask that are above said first area of said substrate;
removing portions of said hard mask not protected by said organic photoresist to leave said hard mask on said first area of said substrate and not on said second area of said substrate;
removing said organic photoresist;
implanting impurities in said second area of said substrate to form source and drain extensions adjacent said second gate conductor;
growing spacers on said second gate conductor;
implanting said impurities in said second area of said substrate to form source and drain regions adjacent said source and drain extensions; and
removing said hard mask using a wet etching process,
said second-type of channel implant, said second gate conductor, and said source and drain regions comprising a transistor.

8. The method according to claim 7, said wet etching process being selective to said substrate and said impurities such that said wet etching process does not damage said substrate, said source and drain extensions, or said source and drain regions.

9. The method according to claim 7, said hard mask comprising one of silicon nitride (Si₃N₄), and germanium silicon oxide (GeSiOx) where Ge composition is at least 60% but less than 100%.

10. The method according to claim 7, said forming of said hard mask comprising:
growing a silicon oxide (SiO₂) liner on said first gate conductor, said second gate conductor, and said substrate; and
depositing a germanium (Ge) layer on said silicon oxide liner.

11. The method according to claim 7, said forming of said hard mask comprising:
depositing a silicon nitride (Si₃N₄) liner on said first gate conductor, said second gate conductor, and said substrate; and
growing a silicon dioxide (SiO₂) layer on said silicon nitride liner.

12. The method according to claim 7, further comprising forming a shallow trench isolation region in said substrate between said first-type of channel implant and said second-type of channel implant.

13. A method of manufacturing an integrated circuit structure, said method comprising:
implanting a first-type of channel implant in a first area of a substrate;
implanting a second-type of channel implant in a second area of said substrate;
forming at least one first gate conductor above said first area of said substrate;
forming at least one second gate conductor above said second area of said substrate;
forming a first hard mask over said first gate conductor, said second gate conductor, and said substrate, said first hard mask comprising one of an oxide and a nitride;
patterning a first organic photoresist over said first hard mask, to leave said first organic photoresist on areas of said first hard mask that are above said first area of said substrate;
removing portions of said first hard mask not protected by said first organic photoresist to leave said first hard mask on said first area of said substrate and not on said second area of said substrate;
removing said first organic photoresist;
implanting impurities in said second area of said substrate to form second source and drain regions adjacent said second gate conductor;
removing said first hard mask using a wet etching process,
forming a second hard mask over said first gate conductor, said second gate conductor, and said substrate, said second hard mask comprising one of an oxide and a nitride;
patterning a second organic photoresist over said second hard mask, to leave said second organic photoresist on areas of said second hard mask that are above said second area of said substrate;
removing portions of said second hard mask not protected by said second organic photoresist to leave said second hard mask on said second area of said substrate and not on said first area of said substrate;
removing said second organic photoresist;
implanting impurities in said first area of said substrate to form first source and drain regions adjacent said first gate conductor; and
removing said second hard mask using a wet etching process,
said first-type of channel implant, said first gate conductor, and said first source and drain regions comprising a first-type transistor
said second-type of channel implant, said second gate conductor, and said second source and drain regions comprising a second-type transistor.

14. The method according to claim 13, said wet etching process being selective to said substrate and said impurities such that said wet etching process does not damage said substrate, said first source and drain regions, or said second source and drain regions.

15. The method according to claim 13, said first hard mask and said second hard mask comprising one of silicon nitride (Si₃N₄), and germanium silicon oxide (GeSiOx) where Ge composition is at least 60% but less than 100%.

16. The method according to claim 13, said forming of said first hard mask and said forming of said second hard mask comprising:
growing a silicon oxide (SiO₂) liner on said first gate conductor, said second gate conductor, and said substrate; and
depositing a germanium (Ge) layer on said silicon oxide liner.

17. The method according to claim 13, said forming of said first hard mask and said forming of said second hard mask comprising:
depositing a silicon nitride (Si₃N₄) liner on said first gate conductor, said second gate conductor, and said substrate; and
growing a silicon dioxide (SiO₂) layer on said silicon nitride liner.

18. The method according to claim 13, further comprising forming a shallow trench isolation region in said substrate between said first-type of channel implant and said second-type of channel implant.

19. A method of manufacturing an integrated circuit structure, said method comprising:
implanting a first-type of channel implant in a first area of a substrate;
implanting a second-type of channel implant in a second area of said substrate;
forming at least one first gate conductor above said first area of said substrate;
forming at least one second gate conductor above said second area of said substrate;
forming a first hard mask over said first gate conductor, said second gate conductor, and said substrate, said first hard mask comprising one of an oxide and a nitride;
patterning a first organic photoresist over said first hard mask, to leave said first organic photoresist on areas of said first hard mask that are above said first area of said substrate;
removing portions of said first hard mask not protected by said first organic photoresist to leave said first hard mask on said first area of said substrate and not on said second area of said substrate;
removing said first organic photoresist;
implanting second-type impurities in said second area of said substrate to form second source and drain extensions adjacent said second gate conductor;
growing second spacers on said second gate conductor;
implanting said second-type impurities in said second area of said substrate to form second source and drain regions adjacent said second source and drain extensions;
removing said first hard mask using a wet etching process,
forming a second hard mask over said first gate conductor, said second gate conductor, and said substrate, said second hard mask comprising one of an oxide and a nitride;
patterning a second organic photoresist over said second hard mask, to leave said second organic photoresist on areas of said second hard mask that are above said second area of said substrate;
removing portions of said second hard mask not protected by said second organic photoresist to leave said second hard mask on said second area of said substrate and not on said first area of said substrate;
removing said second organic photoresist;
implanting first-type impurities in said first area of said substrate to form first source and drain extensions adjacent said first gate conductor;
growing first spacers on said first gate conductor;
implanting said first-type impurities in said first area of said substrate to form first source and drain regions adjacent said first source and drain extensions;
removing said second hard mask using a wet etching process; and
siliciding said first gate conductor, said first source and drain regions, said first source and drain extensions, said second gate conductor, said second source and drain regions, and said second source and drain extensions,
said first-type of channel implant, said first gate conductor, said first source and drain extensions, and said first source and drain regions comprising a first-type transistor,
said second-type of channel implant, said second gate conductor, said second source and drain extensions, and said second source and drain regions comprising a second-type transistor.

20. The method according to claim 19, said wet etching process being selective to said substrate, said first-type impurities, and said second-type impurities such that said wet etching process does not damage said substrate, said first source and drain extensions, said second source and drain extensions, said first source and drain regions, or said second source and drain regions.

21. The method according to claim 19, said first hard mask and said second hard mask comprising one of silicon nitride (Si₃N₄), and germanium silicon oxide (GeSiOx) where Ge composition is at least 60% but less than 100%.

22. The method according to claim 19, said forming of said first hard mask and said forming of said second hard mask comprising:
growing a silicon oxide (SiO₂) liner on said first gate conductor, said second gate conductor, and said substrate; and
depositing a germanium (Ge) layer on said silicon oxide liner.

23. The method according to claim 19, said forming of said first hard mask and said forming of said second hard mask comprising:
depositing a silicon nitride (Si₃N₄) liner on said first gate conductor, said second gate conductor, and said substrate; and
growing a silicon dioxide (SiO₂) layer on said silicon nitride liner.

24. The method according to claim 19, further comprising forming a shallow trench isolation region in said substrate between said first-type of channel implant and said second-type of channel implant.
